(19) United States
(12) Patent Application Publication
(10) Pub. No.: US 2025/0290285 A1
(43) Pub. Date: Sep. 18, 2025

(54) REMOTE CONTROLLED CONSTRUCTION EQUIPMENT WITH A POWER SUPPLY DIAGNOSTICS FUNCTION

(71) Applicant: HUSQVARNA AB, Huskvarna (SE)

(72) Inventor: Tommy OLSSON, Huskvarna (SE)

(21) Appl. No.: 19/076,210

(22) Filed: Mar. 11, 2025

(30) Foreign Application Priority Data
Mar. 14, 2024 (SE) 2450294-0

(51) Int. Cl. E02F 9/20; G01R 19/165; G01R 23/15; G08B 21/18; H02J 3/00

(52) U.S. Cl. CPC E02F 9/205; G01R 19/16547; G01R 23/15; G08B 21/185; H02J 3/0012; H02J 2310/48

(57) ABSTRACT

Electrically powered construction equipment including a remote control device, a control unit, an electrical power sensor, and an electrical power interface arranged to be connected to a power cable, where the power sensor is arranged to monitor an alternating current, AC, over the power interface, and to determine frequency characteristics of the AC over the power interface, where the control unit is arranged to detect a time variation in frequency of the AC based on the determined frequency characteristics, and where the control unit is arranged to trigger one or more automated actions in response to detecting a variation in frequency which fails to meet a frequency acceptance criterion.

### TECHNICAL FIELD

The present disclosure relates to electrically powered construction equipment and to electrically powered remote controlled tracked demolition robots in particular. Aspects of the disclosure also relate to electrical generators. There are disclosed construction equipment, as well as methods and control units for controlling electrically powered construction equipment.

### BACKGROUND

Demolition robots are relatively light-weight and agile construction machines which can be used for various tasks, such as smaller excavation jobs, transportation, and of course demolition tasks.

Demolition robots and other types of heavy-duty construction equipment are often electrically powered via cable from electrical mains at the work site. This power supply may not always be dependable, i.e., may not always be capable of providing stable and sufficient power for completion of a work task at the site. An unstable power supply may complicate the work task and cause unwanted interruptions.

There is a need for improvements in the design of electrically powered construction equipment, and in particular electrically powered tracked demolition robots.

### SUMMARY

It is an object of the present disclosure to provide improved electrically powered construction equipment and electricity generators. The construction equipment comprises a remote control device, a control unit, an electrical power sensor, and an electrical power interface arranged to be connected to an electrical power cable. The power sensor is arranged to monitor an alternating current (AC) over the power interface, and to determine frequency characteristics of the AC over the power interface. In particular, the control unit is arranged to detect a time variation in frequency of the AC in relation to a nominal frequency based on the determined frequency characteristics. The control unit is also arranged to trigger one or more automated actions in response to detecting a variation in frequency which fails to meet a frequency acceptance criterion, in order to adapt operation of the construction equipment to the unstable power supply condition. This way unstable AC supply at a work site can be detected and mitigating actions automatically triggered. The mitigating actions may comprise adjustments in the operations of the equipment to better match the unstable power supply. The actions may also comprise data gathering and communication with a remote server forming part of a back-end system of the equipment, which simplifies trouble-shooting of problems that occur in the equipment. The techniques disclosed herein are not primarily focused on stabilizing the AC supply at a work site but adapting to the unstable AC power supply. More advanced aspects of the techniques disclosed herein relate to also stabilizing the AC power supply at the work site using an on-board energy storage device such as a battery. Such aspects are discussed in more detail below.

The variation in frequency of the AC is often a drop in frequency and a suitable frequency acceptance criterion can be a straight-forward threshold frequency. A drop in frequency may, e.g., be experienced if the external electrical power source is an under-dimensioned generator. The AC monitoring functions can be implemented in power consuming construction equipment such as demolition robots and other electrically powered construction equipment at a work site. However, some AC monitoring functions can also be implemented, at least in part, in generators such as ICE generators and fuel cell stacks. A generator may, e.g., determine that it is under-dimensioned for a given machine connected to the power cable, and communicate this information via wireless link directly to the machine, or to a remote server comprised in a back-end system.

The power sensor is preferably also arranged to determine amplitude characteristics of the AC over the power interface. This allows the control unit to detect a variation in amplitude of the AC in relation to a nominal amplitude based on the determined amplitude characteristics, and to trigger one or more automated actions in response to detecting a variation in amplitude of the AC which fails to meet an amplitude acceptance criterion. The variation in amplitude of the AC may be a drop in voltage and the amplitude acceptance criterion can be a straight-forward voltage threshold. A drop in amplitude, i.e., a drop in voltage, can for instance be experienced if the construction equipment is powered via long cables of insufficient gauge.

It is of course preferred that the control unit is arranged to detect variations in both frequency and amplitude of incoming AC. It is also noted that many of the technical features discussed herein are not inextricably linked to the detection of variation in frequency but can just as well be realized using only detection of time variation in amplitude. This is for instance the case with the herein disclosed technical features relating to communication of data to the back-end system. Detection of variation over time in the frequency of the AC and detection of variation over time in the amplitude of the AC are not inextricably linked to each other and can therefore be practiced separately from each other.

The electrical load by the construction equipment is referred to herein as ego-load, in order to distinguish this load from load by other power consumers connected to the same external power source. According to some aspects, the control unit is arranged to obtain ego-load data indicative of such electric load by the equipment on the electrical power interface. This allows the control unit to determine if a detected variation in the AC over the power interface is due to electric load by the equipment or due to electric load by another power consumer connected to the external electrical power source, based on the ego-load data. Having regard to this ego-load, disturbance on the AC from the external power source can be classified as being due to ego-load or due to load from other power consumers. The control unit can for instance be arranged to detect presence of another power consumer connected to the external electrical power source based on the obtained ego-load data and on the detected variation in the AC over the power interface. For instance, a disturbance on the AC from the external power source which occurs as the construction equipment is idling with small ego-load is most likely due to another power consumer connected to the same external power source as the construction equipment. This is an advantage since it becomes easier to select a suitable mitigating action to be performed in response to detecting a power supply instability.

According to some aspects, the one or more automated actions triggered by the control unit comprises transmitting a status message to a remote server comprised in a back-end system. Several functions can be realized at the back-end given this data. Service support can, for instance, be made better if the service support team has access to information indicating that the power supply at a given work site is unstable.

The one or more automated actions triggered by the control unit may comprise storing data related to an error event together with a time stamp in a digital error log file. This data can be communicated to a remote server comprised in a back-end system or downloaded by an operator at the work site. The data file can be useful when tracing error root causes, diagnosing fault events, and performing general forensics of inconsistent behavior by the construction equipment.

According to some aspects, the one or more automated actions triggered by the control unit comprises generating a warning to an operator of the equipment. The operator then becomes aware of the fact that the power supply is unstable and can therefore better understand the underlying reasons for inconsistent or even erroneous behavior by the equipment.

The one or more automated actions triggered by the control unit may also comprise adjusting an electric load by the equipment on the electrical power interface in response to detecting variation of the AC over the power interface. By adjusting the electrical load by the equipment in this manner, it is possible or even likely that an overload condition at, e.g., a generator used as power source, is alleviated. This automated action may therefore mitigate instability in the AC supply at a work site, which is an advantage.

The control unit is, according to some aspects, configured to operate in a default mode of operation when the power supply is stable. The control unit normally has not adapted any functions and features of its associated construction equipment for operation with an unstable power supply in the default mode of operation. For instance, the control unit normally does not reduce power consumption of the construction equipment when it operates in the default mode of operation. The control unit may, according to some aspects, be configured to adjust an operation of the equipment in response to detecting a variation in frequency of the AC which fails to meet the frequency acceptance criterion. This adjusted operation may be a mode of operation that is specifically tailored for unstable frequency AC power sources, such as under-dimensioned generators and the like. The control unit can also be configured to adjust an operation of the equipment in response to detecting a variation in amplitude of the AC which fails to meet the voltage acceptance criterion. This adjusted mode of operation can be tailored specifically for unstable voltage AC power supplies. By having equipment capable of automatically adjusting its operation in response to detecting instability in the AC power supply at a work site, disruptions in operation by the equipment connected to the AC power supply can be avoided, which is an advantage. The adjustment of operation may for instance comprise a limitation on a rate of increase in electric load by the equipment on the electrical power interface. According to some aspects, the adjusted operation comprises a limitation on electric peak load by the equipment on the electrical power interface.

The control unit may be configured to automatically stop adjusting the operation and to enter back into the default mode of operation when the power source becomes stable again. A hysteresis may be applied to the decision criteria for when to revert back to default mode of operation, i.e., a more stable AC frequency may be required for reverting back into default mode of operation compared to the frequency stability decision criteria used for deciding when to adapt the operation for use with a frequency unstable power source. A timer may also be used, such that the adjusted operation is maintained for a given time period after the power source has stabilized.

The construction equipment may also comprise an on-board energy storage device arranged to store electrical energy and to at least partly power the construction equipment, sometimes referred to as hybrid power construction equipment. The control unit can then be arranged to control a transfer of energy to and/or from the on-board energy storage device based on a detected variation in the AC over the power interface. Most of the time, the control unit will draw power from the on-board energy storage when variation, i.e., instability, is detected in the AC over the power interface. The control unit may also take the opportunity to draw power from the power source to charge the on-board energy storage during time periods when the AC from the power supply at the work site is more stable. The control unit of this hybrid power supply construction equipment can be configured to at least partly power an actuator of the equipment from the on-board energy storage device in case of a detected variation in the AC over the power interface.

According to some aspects, the control unit is configured to stabilize a frequency of the AC over the power interface by outputting electrical power from the on-board energy storage device on the power interface in case of a detected variation in the AC over the power interface. The on-board energy storage device is here used to actively stabilize the AC power supply at a work site, to the benefit of other equipment using the same power source. This way an entire work site can enjoy a stable AC power supply, despite the actual power source being unstable.

The control unit can also be arranged to communicate data to the external power source over a communication channel. The data communicated in this manner can comprise information related to an up-coming electric load by the equipment on the electrical power interface. This allows the external power source to prepare for the upcoming load, which may reduce the disturbance on the AC due to the load. A generator may, e.g., temporarily increase it voltage to make room for the extra load. A slight increase in frequency can also be used, although this must be exercised with caution as an increase in frequency may cause other instabilities in the electrical system at the work site.

The control unit can, optionally, also be arranged to receive data from the external power source over the communication channel. The data thus received may comprise information related to an operating state of the power source. This allows the construction equipment to adapt to the status of the external power source. The construction equipment may, e.g., adapt its power consumption in case the external power source is close to overload. The construction equipment may also choose to increase the load, e.g., to charge an on-board battery source, in case there is a larger margin to the capacity limit of the power source.

There are also disclosed herein methods and various forms of construction equipment associated with the same advantages as discussed above in connection to the control units.

Generally, all terms used in the claims are to be interpreted according to their ordinary meaning in the technical field, unless explicitly defined otherwise herein. All references to “a/an/the element, apparatus, component, means, step, etc.” are to be interpreted openly as referring to at least one instance of the element, apparatus, component, means, step, etc., unless explicitly stated otherwise. The steps of any method disclosed herein do not have to be performed in the exact order disclosed, unless explicitly stated. Further features of, and advantages with, the present invention will become apparent when studying the appended claims and the following description. The skilled person realizes that different features of the present invention may be combined to create embodiments other than those described in the following, without departing from the scope of the present invention.

### BRIEF DESCRIPTION OF THE DRAWINGS

The present disclosure will now be described in more detail with reference to the appended drawings, where:

FIG. 1 illustrates an example demolition robot;

FIG. 2 schematically illustrates construction equipment at a work site connected to a shared electric power source;

FIG. 3 shows an example remote control device;

FIG. 4 schematically illustrates an alternating current (AC);

FIG. 5 shows an example hybrid power system;

FIG. 6 is a flow chart illustrating methods;

FIG. 7 schematically illustrates a control unit; and

FIG. 8 schematically illustrates a computer program product;

### DETAILED DESCRIPTION

Aspects of the present disclosure will now be described more fully with reference to the accompanying drawings. The different devices and methods disclosed herein can, however, be realized in many different forms and should not be construed as being limited to the aspects set forth herein. Like numbers in the drawings refer to like elements throughout.

The terminology used herein is for describing aspects of the disclosure only and is not intended to limit the invention. As used herein, the singular forms “a”, “an” and “the” are intended to include the plural forms as well, unless the context clearly indicates otherwise.

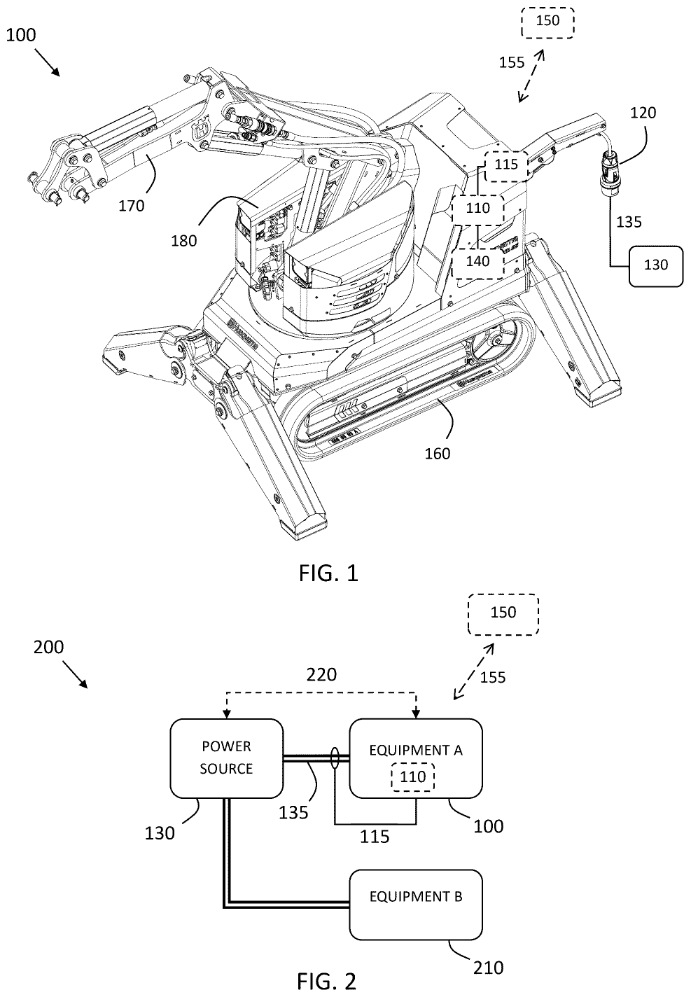

FIG. 1 illustrates an example of electrically powered construction equipment 100, in this case a demolition robot. The disclosure is, however, not limited to demolition robots, but can be applied to most electrically powered construction equipment, including hybrid equipment which comprises an on-board energy storage device that can be used to at least partly power the equipment.

A demolition robot is a light-weight construction machine which can be used for various work tasks, such as smaller demolition tasks. A demolition robot is often tracked, i.e., comprises endless tracks 160 or belts, for support on the ground surface and for propulsion as well as maneuvering.

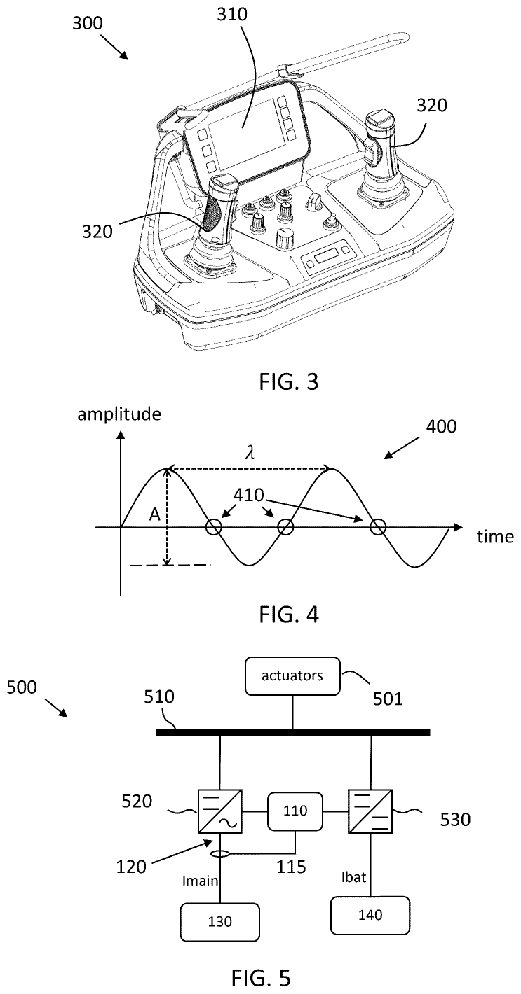

The construction equipment 100 comprises a control unit 110 which controls the general operation of the machine in response to, e.g., user input signals provided by an operator of the machine. The control unit 110 controls actuation of the tracks 160 and the tool carrier arm 170 as well as rotation of the tower 180. Demolition robots are normally remote controlled, which means that they are controlled by an operator from a distance, often via wireless radio link. An example remote control device 300 for use with the construction equipment 100 will be discussed below in connection to FIG. 3. This remote control device is communicatively coupled to the control unit 110 via wireless communication link, although some remote controls also use a wired connection to the control unit. Autonomous construction equipment are also known, which perform work tasks without any direct control by an operator.

A tool such as a breaker, bucket, or steel shears may be supported on the tool carrier arm 170 and used for various work tasks. The equipment 100 is often hydraulically powered, which means that an electric motor drives a hydraulic pump that in turn provides power to the different actuators on the equipment in a known manner.

The control unit 110 and/or the remote control device 300 may be connected to a remote server 150 via wireless link 155. The remote server 150 may implement various service and monitoring functions, as will be discussed in more detail below. The remote server 150 may form part of a back-end system associated with the construction equipment 100. The back-end system can be used for maintenance purposes, trouble-shooting, and general monitoring of the equipment 100.

The construction equipment 100 is electrically powered via an electrical power interface 120. The electrical power interface 120 is arranged to be connected to an external electrical power source 130 via cable 135. The electrical power source 130 is often electrical mains, but can also be a generator, such as an internal combustion engine (ICE) powered or fuel-cell powered generator, which provides alternating current (AC) to the electrical power interface 120. The power interface 120 is normally a three-phase AC power interface. Generators are sometimes also referred to as gensets and may comprise buffer electrical energy storage systems, i.e., battery packs. Generators and gensets are generally known and will therefore not be discussed in more detail herein.

Many of the AC monitoring and instability mitigation techniques can also be implemented at the power source, e.g., in a generator. This generator may be connected to a remote server via wireless link, in order to allow reporting of status messages and the like to the remote server.

It is understood that the external electrical power source is separated from the construction equipment and connected to the construction equipment via cable. The construction equipment may also comprise an on-board electrical energy storage system which can be used to at least temporarily power one or more actuators on the construction equipment, e.g., in the event of power outage of the external power source, or in case of instability in the AC supply from the external power source, as will be discussed in more detail in the following.

The present disclosure is also applicable to other forms of construction equipment, although most of the functions herein are most advantageously used together with remote controlled demolition robots, i.e., hydraulically powered smaller tracked vehicles with a single tool carrier arm 170, often a three-segmented arm, mounted on a rotatable tower 180. The demolition robot is normally controlled by remote control 300 from a location in vicinity of the machine, such as within 30 meters of the machine or so.

Electrically powered construction equipment is often powered via long cables which may cause voltage drops due to insufficient wire gauge (cross-section area of the cable), especially if high power electrical load is applied at the interface 120. Frequency variation in the AC over the power interface 120 may also be experienced at some work sites, in particular work sites where an ICE generator is used as electrical power source 130. This is because most generators take some time to increase the power production in response to a rapid change in load. The ICE of a generator may, e.g., lose rotation speed in response to the increase in torque at the motor axle. This reduction in motor axle speed may in some cases translate directly into a reduction in frequency of the AC output.

A too large drop in voltage over the interface 120 may cause problems in, e.g., electrical motors on the construction equipment 100, such as hydraulic pump motors and other actuator motors, which may experience an increased thermal load due to the increased motor currents that result from a drop in voltage. This increase in thermal load may not be overly problematic as it only occurs during a limited duration of time but can cause large irreparable damage if persistent.

A decrease or drop in AC frequency over the interface 120 in response to an increase in electrical load on the interface is often indicative of that an ICE generator is used to power the construction equipment, and that this generator is overloaded, i.e., that the generator is too small to provide sufficient power. A generator that is overloaded may shut down, or even suffer damage due to the overload, which of course is undesired. A malfunctioning generator will cause undesired interruption in the work task performed by the construction equipment 100.

To improve the situation with unstable power sources at work sites, and provide more robust electrically powered construction equipment, it is proposed to configure one or more electrical power sensors 115 on the construction equipment 100 and use these sensors to monitor various characteristics of the AC over the interface 120, such as frequency and voltage, and also phase and amplitude balance on a three-phase interface. The control unit 110 can then monitor the AC supply from the electrical power source 130 over the cable 135 and quickly detect if there is an undesired variation in frequency and/or in amplitude of the AC, such as a drop in frequency and/or a drop in amplitude which lie outside of predetermined acceptance criteria.

The acceptance criteria can be realized as fixed thresholds or ranges within which the AC frequency and/or AC voltage should lie. A variation in frequency below 5% of nominal frequency may, e.g., be acceptable. A variation in amplitude below, say 10% of nominal voltage may also be acceptable, just to give an example. The acceptance criteria can be predetermined and/or user configurable. Some work sites may have associated acceptance criteria tailored to the specific work site, in order to optimize the different work tasks at the work sites which may be performed by different machines.

The acceptance criteria can also be time-dependent, where a short duration transient in frequency and/or voltage may be acceptable, as long as it does not persist for too long. A time-dependent acceptance criteria preferably comprises less strict acceptance criteria on short-term transient variations, and more strict acceptance criteria on more long term variations. The rationale for accepting more variation in amplitude and frequency over short time periods is that most electric hardware, such as electric motors, can handle a temporary increase in thermal load, whereas a prolonged exposure to incorrect AC can damage the hardware. When the control unit 110 detects a too large variation in AC frequency and/or AC amplitude, one or more automated actions can be triggered to mitigate the consequences of the AC instability. Possible automated actions comprise warnings to an operator, communication of data to a remote server for trouble-shooting and diagnostics purposes, and also adjustments of the operations of the equipment 100 to better suit a given power source. Some aspects of the herein disclosed techniques comprise a communication channel between the control unit of the construction equipment 100 and the power source 130 which is used to power the construction equipment 100. The automated action may then comprise exchange of messages between the construction equipment 100 and the power source, such as a request for increased power send from the construction equipment 100 to the power source 130, and/or a request for decreased load sent from the power source to the construction equipment 100.

To summarize, the present disclosure relates to electrically powered construction equipment 100 comprising a control unit 110, an electrical power sensor 115, and an electrical power interface 120 arranged to be connected to an external electrical power source 130 via cable. The electrical power interface 120 is normally a three-phase AC interface, although other interfaces are also possible. The electrical power sensor 115 is, generally, a device or system arranged to monitor the characteristics of the AC power flowing over the interface 120. According to the present teachings, the electrical power sensor 115 comprises a frequency sensor of some sort that measures the frequency of one or more phases of the interface 120. The frequency sensor may comprise, e.g., a digital frequency meter configured to directly measure the frequency of the AC power, a frequency-to-voltage converter arranged to convert the frequency of the AC power into a proportional voltage, or a phase-locked loop (PLL) that lock onto the frequency of the incoming AC and provides an output signal proportional to the frequency. The power sensor 115 may be implemented as a separate component and the output signal of the power sensor 115 can then be fed to the control unit 110 for further processing. The power sensor 115 can also be integrally formed with the control unit 110, i.e., comprised in the same physical unit as the processing circuitry of the control unit 110. The power sensor determines frequency characteristics of the AC over the power interface, which is to be construed broadly to mean that the power sensor at least provides some form of data from which frequency can be inferred or determined. It is appreciated that the power sensor does not have to be configured to perform any advanced processing of the measured data.

The power sensor 115 is arranged to monitor the AC over the power interface 120, and to determine frequency characteristics of the AC over the power interface 120. The frequency characteristics may comprise just an instantaneous frequency of the different phases of the AC over the interface 120. However, it may also comprise data related to phase relationships, phase balance and amplitude balance between the phases of a three-phase AC interface. Data indicative of a frequency spectrum of the AC on the interface 120 may also be of interest, since it shows if there are unwanted spurious frequencies present, and if there is noise and distortion on the AC phase signals. This data from the power sensor can be processed by the control unit 110 or sent to the remote server 150 for further processing.

The remote server 150 may form part of a back-end system that is configured to receive data indicative of various detected time variations in frequency and/or amplitude of the AC over the interface 120. The back-end system can then determine a root cause of a malfunction or performance degradation that a given piece of equipment 100 has experienced. For instance, an operator of the equipment 100 may experience problems during use of the equipment 100 at some work site and may suspect that there is a problem with the equipment. The operator may then call a service support center to report the problems. The service support center, having access to the back-end system, can then determine that the most likely cause of the experienced problems relates to the power supply at the work site, and not to the actual equipment 100. A recommendation can then be given to the operator to improve the power supply, which should remedy or at least mitigate the problems experienced at the work site.

FIG. 4 schematically illustrates a sinusoidal AC 400 as function of time. The frequency of the AC can be determined in various ways. One way is to determine the average time duration A between peaks which is associated with the wavelength of the sinusoid and therefore also its frequency. The instantaneous frequency of the sinusoidal waveform can also be determined as the number of times the signal has a zero-crossing 410 in a given time period. The amplitude A of the sinusoid is also indicated in FIG. 4. This amplitude is associated with the voltage of the electric current. In case of a three-phase AC, three sinusoids carry the electrical power over the interface 120 in a known manner. The relative phases of these three sinusoids can also be of interest if it is desired to determine if the power supply provides a stable and clean electric current, or if the power supply is corrupted by one or more forms of imbalances and distortion components.

The control unit 110 is, generally, arranged to detect a variation in frequency of the AC in relation to a nominal frequency based on the determined frequency characteristics, such as a drop in frequency or an instability in the frequency, i.e., a deviation from a stable sinusoidal signal at a nominal frequency, and to trigger one or more automated actions in response to detecting a variation in frequency which fails to meet a frequency acceptance criterion.

Most of the unstable power supply adaptations and functions described herein are advantageously implemented in various forms of power consuming construction equipment, such as tracked demolition robots and other electrically powered work tools that consume electrical power during operation. However, many of the different functions and technical features described herein can also be implemented at the power source, i.e., at a generator arranged to provide electrical power to a power cable that powers, e.g., a demolition robot.

The variation in frequency of the AC may for instance be a detected drop in frequency and the frequency acceptance criterion can be a straight-forward threshold frequency against which the measured AC frequency is compared. A variation is then detected if the instantaneous frequency of the AC over the interface 120 drops below the frequency threshold. A hold time may also be applied, in order to make the system more robust to transients. A variation is then detected if the instantaneous frequency falls below the frequency threshold and stays below the threshold for a predetermined period of time. Another option is to count the number of times the instantaneous frequency falls below the threshold in a time period and detect a variation in the AC over the interface 120 if the frequency falls below the threshold too often in a given period of time.

The acceptance criterion can also comprise more advanced aspects, such as an acceptable range of variation in frequency as function of time. Transient short-term variation may be acceptable as long as they do not persist for too long, as discussed above. Various automated actions can be triggered in response to detecting unsound variation in the AC over the interface 120, as will be discussed in the following. An acceptance criterion on spectral widening can also be applied, i.e., a requirement that the AC should comprise a single clear tone, and not a sum of different frequencies over a frequency band.

The power sensor 115 can also be arranged to determine amplitude characteristics of the AC over the power interface 120, in addition to the frequency characteristics, i.e., voltage characteristics of the AC over the interface 120. The control unit 110 can then be arranged to detect a variation in amplitude of the AC in relation to a nominal amplitude based on the determined amplitude characteristics, and to trigger one or more automated actions in response to detecting a variation in amplitude of the AC which fails to meet an amplitude acceptance criterion. According to an example, the variation in amplitude of the AC can be a drop in voltage and the amplitude acceptance criterion can be a voltage threshold. As for frequency, more advanced acceptance criteria can also be applied. In case the electrical power interface 120 is a three-phase interface, then voltage balance between the three phases can also be of interest. An imbalance in the voltage of the different phases may cause problems in many different types of electrical hardware. The control unit 110 can detect such imbalance by means of the power sensor 115 and execute mitigating actions in response to the voltage imbalance.

It is appreciated that the detection of variation in amplitude is not inextricably linked to the detection of variation in frequency. Hence, the aspects comprising detection of variation in amplitude of the present teaching can be implemented separately from the aspects comprising detection of variation in AC frequency at the electrical power interface 120. Consequently, there is disclosed herein electrically powered construction equipment 100 comprising a control unit 110, an electrical power sensor 115, and an electrical power interface 120 arranged to be connected to an external electrical power source 130. The power sensor 115 is arranged to monitor AC over the power interface 120, and to determine amplitude characteristics of the AC over the power interface 120, where the control unit 110 is arranged to detect a time variation in amplitude of the AC in relation to a nominal amplitude based on the determined amplitude characteristics, and where the control unit 110 is arranged to trigger one or more automated actions in response to detecting a variation in amplitude which fails to meet an amplitude acceptance criterion.

According to an example, variation such as a drop in frequency and/or amplitude of the AC over the interface 120 is calculated concurrently over one or more time windows of different lengths. In other words, a metric such as

$${\overline{σ}}_{{T}_{w}} = \frac{1}{{T}_{w}} {\int }_{t = 0}^{t = {T}_{w}} σ ( t ) d t$$

can be determined, where σ(t) is the instantaneous variation or difference from a nominal value determined at time t. The metric is determined for different time window durations T_{w}, such as 0.1, 0.5, 1, 2 and 5 seconds. It is noted that many different types of averages can be calculated, such as weighted averages. Each average value metric will have a different acceptance criterion, such as a threshold value. For example:

$${\overline{σ}}_{{T}_{w = 0.1 s}} < 3 {σ}_{N}$$

$${\overline{σ}}_{{T}_{w = 0.5 s}} < 2 {σ}_{N}$$

$${\overline{σ}}_{{T}_{w = 1 s}} < 1.5 {σ}_{N}$$

$${\overline{I}}_{{T}_{w = 2 s}} < 1.25 {σ}_{N}$$

$${\overline{I}}_{{T}_{w = 5 s}} < 1.0 {σ}_{N}$$

where σ_{N} is some nominal variation. The threshold values and factors above are just examples and are not to be construed as limiting to the disclosure. A transient drop in AC frequency or amplitude which only persists for a short duration of time may then be deemed acceptable, while the same drop in AC frequency or amplitude may not be acceptable if it stays for too long, since then hardware in the construction equipment 100 and/or at the external power source 130 may suffer permanent damage.

The one or more automated actions triggered by the control unit 110 may comprise generating a warning to an operator, e.g., as a displayed message, a warning buzzer, or a warning light. The operator is then made aware of the unstable power supply, and can take action, e.g., by inactivating other machines drawing power from the same power source, or by adjusting the way the equipment 100 is controlled so as to draw less power from the power source 130. The warning may be issued via the display 310 at the remote control, or via some other human-machine-interface (HMI).

The one or more automated actions triggered by the control unit 110 may also comprise storing data related to an error event together with a time stamp in a digital error log file. This error log file can be retrieved and used for trouble-shooting if the equipment 100 suffers from malfunction. The error log file can be stored locally at the machine, and also transmitted to the remote server 150, where it can be used in the back-end system for analysis.

According to another example, the one or more automated actions triggered by the control unit 110 comprises adjusting an electric load by the equipment 100 on the electrical power interface 120 in response to detecting variation of the AC over the power interface 120. Adjusting the electric load by the equipment 100 on the electrical power interface 120 can be done in many ways, e.g., by enforcing a hydraulic flow limitation as function of hydraulic pressure in a hydraulic system of the equipment 100 or by restricting the operations of the equipment 100 to operations that do not draw peak power.

According to some aspects, the one or more automated actions triggered by the control unit comprises transmitting a status message to a remote server comprised in a back-end system. This status message may, e.g., comprise data indicative of a detected variation in frequency and/or amplitude of the AC over the power interface. The data may also comprise information related to a phase relationship of a three-phase AC power supply. The back-end system was discussed above. This data enables improved trouble-shooting and also simplifies maintenance and servicing decisions. Construction equipment exhibiting unexpected and/or inconsistent behavior at some work site may be diagnosed as having an unreliable power supply, which means that the construction equipment does not have to be serviced, since the experienced problems with the construction equipment are most likely due to the external power source and not to the construction equipment.

The hydraulic power is related to the total power consumption of the construction equipment 100 in a known manner, and it is approximately proportional to both the pressure and the flow. As a simple approximation, hydraulic power equals the product of hydraulic flow and hydraulic pressure in the hydraulic system. In simplified terms, the formula for hydraulic power output is Power=Q×P, where Q is the flow rate in liters per minute, and P is the pressure in bars, i.e., power is normally at least approximately proportional to both pressure and flow. To limit the electrical load on the interface 120, the control unit 110 can impose a flow limitation on the hydraulic system when pressure in the hydraulic system rises, such that the product of pressure and flow is kept below some limit.

Some construction equipment 100 comprise on-board energy storage devices 140, or auxiliary power source, which can be used as supplement to the power drawn over the interface 120. SE542381C2 for instance describes a demolition robot with an on-board battery pack that can be used to at least partly power the actuators on the robot in case of a power deficit on an electrical mains connection. Hybrid power systems suitable for demolition robots will also be discussed below in connection to FIG. 5. According to the present teachings, the control unit 110 may control the power system of the equipment 100 to draw power from the auxiliary power source when a variation in the AC over the interface 120 has been detected by the power sensor 115. The equipment 100 then becomes less sensitive to the disturbance on the main electrical power supply, and the load on the power source 130 is also reduced.

The load by the equipment 100 on the electrical power interface 120 (and on the electrical power source 130) will be referred to as ego-load herein, to separate the load by the equipment 100 from other loads which may be present, i.e., electrical loads from equipment different from the equipment 100.

The control unit 110 can also be arranged to obtain ego-load data related to an electric load by the equipment 100 on the electrical power interface 120. The ego-load data can be determined based on the power drawn by the equipment 100 over the interface 120. The ego-load data can also be determined based on a present operation or set-point of one or more actuators on the construction equipment, since this is indicative of how much power the equipment 100 draws over the interface 120. The control unit 110 can then be configured to determine if a detected variation in the AC over the power interface 120 is due to electric load by the equipment 100 or due to electric load on the power source 130 by another power consumer connected to the external electrical power source 130, based on the ego-load data. If the detected variation in AC over the interface 120, i.e., the detected variation in frequency and/or amplitude of the electrical current over the interface 120, is correlated in time with an increased power consumption by the construction equipment 100, then it can be suspected that the construction equipment 100 is causing the variation in AC. This variation could be due to that a too small generator is used to provide electrical power to the equipment, and/or that the cables 135 between the power source 130 and the equipment 1200 are too long.

Dropping frequency or variation in frequency as a result of an applied electrical load by the equipment 100 indicates that a generator such as an ICE generator is used as power source 130. This is because it takes some time for a generator to generate power in response to an increased load, which may cause the frequency to drop at least temporarily. This information may be communicated to the operator, e.g., via a display 310 on the remote control device 300. The information may also be communicated to the remote server 150, where it can be used to facilitate trouble-shooting. The information may be communicated at least in part as tactile information, e.g., via the joysticks 320 of the remote control device 300.

If frequency and voltage drops during increased load by the equipment 100 it is likely that a too small generator is used, or a combination of a small generator and long cables with insufficient wire gauge. This can also be communicated to an operator via the display 310, informing him or her of the fact that the power supply is unstable. The operator can then take action, such as disconnecting other equipment or adjusting the way the equipment is used so as to reduce the load on the power source 130.

If frequency and voltage drops without a concurrent increased load by the equipment, i.e., if the ego-load did not increase in connection to the detected variation in AC over the interface 120, then it is likely that other power consumers are operating on the same generator and may affect total load on the power source 130. This information can be communicated to the operator of the equipment 100, e.g., via the display 310, and also communicated to back-end, i.e., the remote server 150, where it can be used for trouble-shooting and for diagnostics purposes.

If the AC frequency over the interface 120 is stable, i.e., if there is no significant variation in the AC over the interface 120, but there is a variation such as a drop in voltage during increased load (increased current) by the equipment 100, then it is likely that the power source 130 is electrical mains and that the cable 135 is too long and/or has too small gauge.

If the AC frequency is stable but there is a drop in voltage without increased ego-load by the equipment 100, then it is likely that other equipment is causing a voltage instability in the power supply. The control unit can infer this information 110, having regard to the output from the power sensor 115 in combination with information about the ego-load of the equipment 100.

The control unit may be arranged to adjust an operation of the equipment in case the power sensor 115 detects frequency variation, and in particular a frequency drop in response to significant electric load by the equipment 100 on the interface 120. This adjustment of operation by the equipment may be referred to as a generator-assist mode of operation since the operations by the equipment becomes more robust to unstable frequency power sources. The generator-assist mode of operation may, e.g., be entered into by the control unit 110 if repeated occurrences of frequency loss are detected as a consequence of electric load by the equipment 100 on the interface 120. The generator-assist mode of operation is a mode that is specifically tailored operation together with a genset as power source, such as an ICE generator. The control unit 110 may for instance control the power consumption of the equipment 100 so as to ramp up more slowly in order to allow the generator to increase power output in response to the load by the equipment 100. The construction equipment may also impose a restriction on power to not overload the generator. The control unit 110 may, for instance, be configured to determine at which AC power over the interface 120 the AC variation starts to occur, and limit power consumption of the equipment 100 to be below this power. To summarize, the control unit 110 can, generally, be configured to adjust an operation in response to detecting a variation in frequency of the AC which fails to meet the frequency acceptance criterion. The adjustment of operation may comprise a limitation on a rate of increase in electric load by the equipment 100 and/or a limitation on electric peak load by the equipment 100 on the electrical power interface 120.

The control unit 110 can also be configured to adjust an operation in response to detecting a variation in amplitude of the AC which fails to meet the voltage acceptance criterion. The adjusted operation may comprise a limitation on a rate of increase in electric load by the equipment 100 on the electrical power interface 120 and/or a limitation on electric peak load by the equipment 100 on the electrical power interface 120. This type of adjusted mode of operation may be referred to as a long cable adapted mode of operation, since it makes the equipment more robust to unstable power caused by too long cables.

The control unit may be configured to stop adjusting the operation of the equipment and enter back into its default mode of operation when the power source becomes stable again. A hysteresis may be applied to the detection criteria which triggers reverting back into the default mode of operation, i.e., a more stable frequency than the threshold used to detect the frequency variation may be used as criteria for detecting a stable frequency power supply. A timer may also be used, such that the adjusted operation is maintained for a given time period after the power source has stabilized.

FIG. 2 shows an example work site 200 with a power source 130 that is used to power equipment A 100 and equipment B 210. The two pieces of equipment may, e.g., be two different demolition robots, or a demolition robot and some other machine. Equipment A comprises a power sensor 115 and the control unit 110 discussed above. Equipment B may be a legacy type demolition robot, or some other type of heavy-duty construction equipment that consumes power from the power source 130. In case the power source 130 does not have sufficient capacity to provide peak power to equipment B, it is likely that the power sensor 115 in equipment A detects a disturbance on the power cable 135 when high load is placed on the power source.

The control unit 110 can be arranged to detect presence of another power consumer connected to the external electrical power source 130 based on the obtained ego-load data and on the detected variation in the AC over the power interface 120. If the power sensor 115 measures a variation in frequency and/or amplitude when the ego-load is low or non-existent, then it can be deduced that another power source is drawing power from the same power source 130, and that this equipment is causing overload at the power source.

Some construction equipment 100 may be capable of communicating with nearby equipment, such as a generator, via a communication channel 220. The communication may take place via a wireless link similar to that used to connect the remote control device 300 to the control unit 110. In this case the construction equipment 100 and the power source 130 can cooperate in a coordinated manner in order to reduce variation in the AC over the interface 120, in terms of frequency and/or amplitude. The construction equipment 100 may, e.g., communicate that it is about to draw power over the interface, and possibly also how much power that the construction equipment 100 intends to draw over the interface. In other words, the control unit 110 can be arranged to communicate data to the external power source 130 over a communication channel 220, which data comprises information related to a future electric load by the equipment 100 on the electrical power interface 120. The generator, in response to receiving this heads-up notification, can preemptively start to ramp up power production, such that when the load increases the generator already has built up some excess power. The generator may increase voltage to be a few percent above nominal voltage, such as 5% above nominal voltage in response to receiving the notification from the construction equipment 100 over the communication channel 220. The generator can also increase the frequency of the AC slightly in order to prepare for the upcoming increase in load. An increase in frequency can, however, only be applied in case the generator is operating in island mode, without connection to other power sources and in particular without connection to electrical mains without some buffer or frequency separation there inbetween.

The communication channel 220 can also be used by the power source 130 to communicate data to the control unit 110 associated with an operating condition of the power source 130, such as if the power source is experiencing an overload condition, or not. The control unit 110 can then adjust an operation of the equipment 100 so as to not overload the power source. The communication channel 220 between power source and construction equipment 100 is particularly useful when the construction equipment 100 is operating in the generator-assist mode of operation or in some other adjusted mode of operation in order to make the equipment more robust to instability in the power supply.

With reference to FIG. 1 and also to FIG. 5, some example construction equipment comprises an on-board energy storage device 140 arranged to store electrical energy and to at least partly power actuators 160, 170, 180 on the construction equipment 100. The control unit 110 can then be arranged to control a transfer of energy to and/or from the on-board energy storage device 140 based on a detected variation in the AC over the power interface 120. The control unit 110 can for instance be configured to at least partly power a device of the equipment 100 from the on-board energy storage device 140 in case of a detected variation in the AC over the power interface 120.

The schematically illustrated example hybrid power system 500 in FIG. 5 comprises a direct current (DC) bus 510 that powers one or more actuators 501 on the construction equipment 100 in a known manner. The DC-bus 510 may, e.g., provide electrical power directly or via inverters to hydraulic pump drive motors and other electrically powered actuators. Electrical power is provided to the DC bus by an inverter 520 which connects the DC bus 510 to the AC power source 130 (via the power interface 120) and also by a DC/DC block 530 that connects the DC bus to an auxiliary energy source, such as an electrical energy storage device 140. The control unit 110 may control the inverter 520 and the DC/DC block 530 concurrently so as to reduce the power consumption over the interface 120 to be at or below the capability of the power source 130. In other words, once the control unit 110 starts to detect a disturbance in the AC over the interface 120, it starts to use the auxiliary energy source to complement the main power source. The current drawn from the power source 130 Imain is then reduced, while the current Ibat drawn from the auxiliary energy source is increased by a corresponding amount.

The control unit 110 can also be configured to stabilize a frequency of the AC over the power interface 120 by outputting electrical power from the on-board energy storage device 140 on the power interface 120 in case of a detected variation in the AC over the power interface 120. In this case the construction equipment 100 acts as a power stabilizer, which provides a more stable power supply at a work site, to the benefit of other construction equipment. To stabilize the frequency of the AC over the interface 120, the construction equipment 100 can draw power from the on-board energy storage device 140 over the DC/DC block 530 and output this power by the inverter 520 onto the power interface 120. This reduces the load on the power source 130, which may then be able to provide the desired AC amplitude and frequency. The output power should be frequency locked to the AC frequency of the power source so as to not cause further frequency instability. It is most common to stabilize frequency by outputting power from the on-board energy storage device 140 to the power interface. However, in some cases it may also be possible to stabilize frequency by transferring power from the power interface to the on-board energy storage device 140, e.g., in case of a power surge on the power interface.

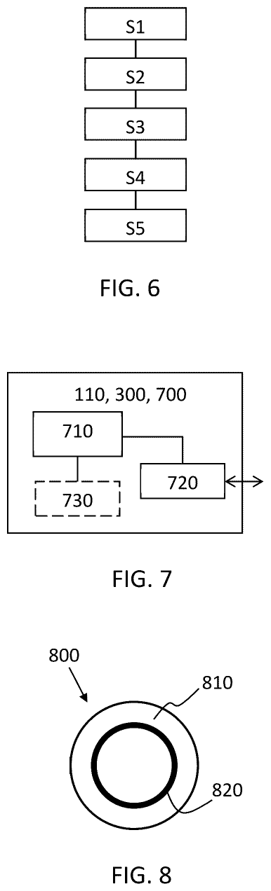

FIG. 6 is a flow chart illustrating a method which summarizes at least some of the techniques discussed above. FIG. 6 illustrates a computer-implemented method performed by a control unit 110. The method comprises obtaining S1 data from an electrical power sensor 115 of the construction equipment 100, by the control unit 110, where the power sensor 115 is arranged in connection to a power interface 120 of the construction equipment 100, monitoring S2 an AC over the power interface 120, by the power sensor 115, determining S3 frequency characteristics of the AC over the power interface 120, detecting S4 a time variation in frequency of the AC in relation to a nominal frequency based on the determined frequency characteristics, by the control unit 110, and triggering S5 one or more automated actions in response to detecting a variation in frequency which fails to meet a frequency acceptance criterion.

FIG. 7 schematically illustrates, in terms of a number of functional units, the general components of the control unit 700, such as the control unit 110 discussed above and the remote control device 300. Processing circuitry 710 is provided using any combination of one or more of a suitable central processing unit CPU, multiprocessor, microcontroller, digital signal processor DSP, etc., capable of executing software instructions stored in a computer program product, e.g., in the form of a storage medium 730. The processing circuitry 710 may further be provided as at least one application specific integrated circuit ASIC, or field programmable gate array FPGA.

Particularly, the processing circuitry 710 is configured to cause the demolition robot 100 to perform a set of operations, or steps, such as the methods discussed in connection to FIG. 6 and the discussions above. For example, the storage medium 730 may store the set of operations, and the processing circuitry 710 may be configured to retrieve the set of operations from the storage medium 730 to cause the device to perform the set of operations. The set of operations may be provided as a set of executable instructions. Thus, the processing circuitry 710 is thereby arranged to execute methods as herein disclosed.

The storage medium 730 may also comprise persistent storage, which, for example, can be any single one or combination of magnetic memory, optical memory, solid state memory or even remotely mounted memory.

The control unit 700 may further comprise an interface 720 for communications with at least one external device. As such the interface 720 may comprise one or more transmitters and receivers, comprising analogue and digital components and a suitable number of ports for wireline or wireless communication.

The processing circuitry 710 controls the general operation of the control unit 700, e.g., by sending data and control signals to the interface 720 and the storage medium 730, by receiving data and reports from the interface 720, and by retrieving data and instructions from the storage medium 730.

FIG. 8 illustrates a computer readable medium 810 carrying a computer program comprising program code means 820 for performing the methods illustrated in FIG. 6, when said program product is run on a computer. The computer readable medium and the code means may together form a computer program product 800.

1. Construction equipment comprising a remote control device, a control unit, an electrical power sensor, and an electrical power interface arranged to be connected to a power cable at a construction work site,
wherein the power sensor is arranged to monitor an alternating current, AC, over the power interface, and to determine frequency characteristics of the AC over the power interface,
wherein the control unit is arranged to detect a time variation in frequency of the AC based on the determined frequency characteristics, and
wherein the control unit is arranged to trigger one or more automated actions in response to detecting a variation in frequency which fails to meet a frequency acceptance criterion.

2. The construction equipment according to claim 1, wherein the one or more automated actions comprises generating a warning to an operator of the equipment, via the remote control device.

3. The construction equipment according to claim 1,
wherein the power sensor is arranged to determine amplitude characteristics of the AC over the power interface,
wherein the control unit is arranged to detect a variation in amplitude of the AC in relation to a nominal amplitude based on the determined amplitude characteristics,
wherein the control unit is arranged to trigger one or more automated actions in response to detecting a variation in amplitude of the AC which fails to meet an amplitude acceptance criterion.

4. The construction equipment according to claim 1,
wherein the construction equipment is power consuming equipment arranged to draw electrical power over the power cable,
wherein the control unit is arranged to obtain ego-load data indicative of an electric load by the equipment on the electrical power interface,
wherein the control unit is arranged to determine if a detected variation in the AC over the power interface is due to electric load by the equipment or due to electric load by another power consumer connected to an external electrical power source providing power to the power cable, based on the ego-load data.

5. The construction equipment according to claim 4,
wherein the control unit is arranged to detect presence of another power consumer connected to an external electrical power source providing power to the power cable, based on the obtained ego-load data and on the detected variation in the AC over the power interface.

6. The construction equipment according to claim 1,
wherein the one or more automated actions triggered by the control unit comprises transmitting a status message to a remote server comprised in a back-end system.

7. The construction equipment according to claim 1,
wherein the one or more automated actions triggered by the control unit comprises storing data related to an error event together with a time stamp in a digital error log file.

8. The construction equipment according to claim 1,
wherein the one or more automated actions triggered by the control unit comprises adjusting an electric load by the equipment on the electrical power interface in response to detecting variation of the AC over the power interface.

9. The construction equipment according to claim 1,
wherein the control unit is configured to adjust an operation of the equipment in response to detecting a variation in frequency of the AC which fails to meet the frequency acceptance criterion.

10. The construction equipment according to claim 4,
wherein the control unit is configured to adjust an operation of the equipment in response to detecting a variation in amplitude of the AC which fails to meet the voltage acceptance criterion, wherein the adjustment of operation comprises a limitation on a rate of increase in electric load by the equipment on the electrical power interface, or a limitation on electric peak load by the equipment on the electrical power interface.

11. The construction equipment according to claim 1,
comprising an on-board energy storage device arranged to store electrical energy and to at least partly power the construction equipment or provide electrical power to the cable,
wherein the control unit is arranged to control a transfer of energy to and/or from the on-board energy storage device based on a detected variation in the AC over the power interface.

12. The construction equipment according to claim 11,
wherein the control unit is configured to at least partly power an actuator of the equipment from the on-board energy storage device in case of a detected variation in the AC over the power interface.

13. The construction equipment according to claim 11,
wherein the control unit is configured to stabilize a frequency of the AC over the power interface by outputting electrical power from the on-board energy storage device on the power interface in case of a detected variation in the AC over the power interface.

14. The construction equipment according to claim 1,
wherein the control unit is arranged to communicate data over a communication channel to an external power source connected to the power cable,
wherein the data comprises information related to an up-coming electric load by the equipment on the electrical power interface.

15. The construction equipment according to claim 1,
wherein the control unit is arranged to receive data over the communication channel from an external power source connected to the power cable,
wherein the data comprises information related to an operating state of the power source.

16. A computer-implemented method performed by a control unit, the method comprising
obtaining data from an electrical power sensor of the construction equipment, by the control unit, wherein the power sensor is arranged in connection to a power interface of the construction equipment,
monitoring an alternating current, AC, over the power interface, by the power sensor,
determining frequency characteristics of the AC over the power interface,
detecting a time variation in frequency of the AC in relation to a nominal frequency based on the determined frequency characteristics, by the control unit, and
triggering one or more automated actions in response to detecting a variation in frequency which fails to meet a frequency acceptance criterion.

17. Electrically powered construction equipment comprising a control unit, an electrical power sensor, and an electrical power interface arranged to be connected to a power cable,
wherein the power sensor is arranged to monitor an alternating current, AC, over the power interface, and to determine amplitude characteristics of the AC over the power interface,
wherein the control unit is arranged to detect a time variation in amplitude of the AC in relation to a nominal amplitude based on the determined amplitude characteristics, and
wherein the control unit is arranged to trigger one or more automated actions in response to detecting a variation in amplitude which fails to meet an amplitude acceptance criterion.

18. Electrically powered construction equipment comprising a control unit, an electrical power sensor, and an electrical power interface arranged to be connected to a power cable,
wherein the power sensor is arranged to monitor an alternating current, AC, over the power interface, and to determine frequency and/or amplitude characteristics of the AC over the power interface,
wherein the control unit is arranged to detect a time variation in frequency and/or amplitude of the AC in relation to a nominal frequency and/or amplitude based on the determined characteristics, and
wherein the control unit is arranged to communicate data indicative of the detected time variation to a remote server comprised in a back-end system associated with the construction equipment, or
wherein the control unit is arranged to control a transfer of energy to and/or from the on-board energy storage device based on a detected variation in the AC over the power interface, or
wherein the control unit is configured to stabilize a frequency of the AC over the power interface by transferring electrical power to or from the on-board energy storage device on the power interface in case of a detected variation in the AC over the power interface.
